(19) United States
(12) Patent Application Publication
(10) Pub. No.: US 2006/0071255 A1
(43) Pub. Date: Apr. 6, 2006

(54) Non-destructive read ferroelectric memory cell, array and integrated circuit device

(76) Inventors: Bomy Chen, Cupertino, CA (US); Dana Lee, Santa Clara, CA (US); June Han, Fremont, CA (US)

Correspondence Address: DLA PIPER RUDNICK GRAY CARY US, LLP, 2000 UNIVERSITY AVENUE, E. PALO ALTO, CA, 94303-2248, US

(21) Appl. No.: 10/949,778

(22) Filed: Sep. 24, 2004

(51) Int. Cl. H01L 29/94

(52) U.S. Cl. 257/295

(57) ABSTRACT

A ferroelectric memory cell has a semiconductor substrate of a first conductivity type having a first region and a second region with each being of a second conductivity type, with a channel region therebetween. The first region and the second region are aligned in a first direction. A gate dielectric is over at least a portion of the channel region. A gate is over the gate dielectric, with the gate extending in a direction transverse to the first direction termination at a termination point not overlapping the first region, the second region and the channel region. A ferroelectric capacitor is at the termination point. The ferroelectric capacitor has a first end and a second end with the first end connected to the gate. The ferroelectric memory cell has three terminals: the first region, the second region, and the second end. In another embodiment, an insulator is over at least a portion of the first region. The gate has one end over the gate dielectric and extends over the insulator terminating at a termination point. A ferroelectric capacitor is connected to the termination point, which lies over a portion of the first region.

### TECHNICAL FIELD

The present invention relates to a ferroelectric memory cell, and more particularly to a non-destructive read ferroelectric memory cell, and an array of such cells for use either as an integrated memory device or as an integrated embedded controller device with memory on board.

### BACKGROUND OF THE INVENTION

A ferroelectric memory cell is well known in the art. Referring to FIG. 1, there is shown a schematic representation of a ferroelectric memory cell 10 of the prior art. The memory cell 10 comprises a conventional MOS transistor having a first region 14 (source or drain), and a second region 12 (drain or source) separated by a channel region. A gate 16 controls the conduction of charges within the channel region between the source/drain 14 to the drain/source 12. A ferroelectric memory capacitor 20 comprising of a first electrode 20a and a second electrode 20b spaced apart therefrom is connected to one of the regions 14 or 12. In the example shown in FIG. 1, the ferroelectric capacitor 20 is connected such that its first electrode 20a is connected to the first region 14 of the MOS transistor. The second electrode 20b of the ferroelectric cell 20 is connected to ground.

In the operation of the ferroelectric memory cell 10 shown in FIG. 1, the ferroelectric capacitor 20 stores an electric polarization in the absence of an applied electric field. A film of ferroelectric material in crystalline form is deposited between the two electrodes 20a and 20b to form the ferroelectric capacitor 20. The ferroelectric capacitor 20 stores data within a crystalline structure. These “Perovskite” crystals maintain two stable states which form a binary bit. However, in a read operation, in order to read a ferroelectric capacitor 20 it is necessary to detect the position of the atoms within the Perovskite crystals. Unfortunately, the state of the Perovskite crystal cannot be directly sensed. As a result, an electric field is applied across the capacitor 20. The mobile atom will move across the crystal in the direction of the field if they are not already in the appropriate position. In the middle of the crystal, a high energy state holds the atoms in place when no field is present. As the atoms move though this high energy state, a charge spike is emitted. A circuit dumps the charge that results from the applied field from the capacitor 20 and then pairs it to the charge from a reference. Thus, a capacitor 20 with atoms that switch states would emit a larger charge than a capacitor 20 with atoms that do not switch states. Unfortunately, a read operation necessarily destroys the state. Therefore, at the end of the read operation, the state of the capacitor 20 must be restored.

Referring to FIG. 2 there is shown another ferroelectric memory cell 110 of the prior art. Such a cell is disclosed in a document published at ISSCC95 entitled “A Single-Transistor Ferroelectric Memory Cell” by Takashi Nakamura, et al., 1995 IEE International Solid State Conference. In this embodiment, the ferroelectric capacitor 20 is connected to the gate 16 rather than to either of the regions 14 or 12. Thus, the second electrode 20b is electrically connected or acts as the gate for the MOS transistor. The ferroelectric memory cell 110 that results from this configuration has three terminals: a first terminal which is the source/drain region 12, a second terminal, which is the source/drain region 14, and a third terminal which is the first electrode 20a of the ferroelectric capacitor 20.

Although in operation, the ferroelectric memory cell 110 shown in FIG. 2 does not exhibit destructive read, it is difficult to manufacture. In particular, because the material, such as PZT and Ir/IrO₂ are used as the Perovskite crystal and the material, such as Y, are used as the first and second electrodes 20a and 20b respectively, they are not the materials that are “normally” used in semiconductor manufacturing. The manufacturing processes for the ferroelectric capacitor 20 and the MOS transistor are difficult to integrate. In particular, the etching of the ferroelectric capacitor 20 can result in a tall-slope resulting from an ion-milling etch of the capacitor 20. In addition, the complex ion-milling etch process cannot stop on the gate oxide which typically is immediately above the semiconductor substrate. Therefore, damage of the thin gate oxide is a possibility. In addition, by having the ferroelectric capacitor 20 so close to the gate region 16, there is the potential for extra disturbance by the ferroelectric capacitor 20 being closely coupled between the bottom electrode 20b and the bit line connected to either the source/drain 14 or the source/drain 12. Finally, if the ferroelectric capacitor 20 were used as a ferroelectric memory cell 110 in an integrated embedded controller, the integration of the process to make the ferroelectric memory cell 110 with the process to make the controller portion of the integrated embedded product which uses extensively metallization technology such as cobalt silicide and copper interconnect, can pose additional problems.

The use of a capacitor having uneven surfaces to increase the capacitance is well known in the art. See, for example, U.S. Pat. No. 5,561,311 with regard to the disclosure of a capacitor in a DRAM memory cell.

Accordingly, it is one object of the present invention to make a ferroelectric memory cell which is more readily manufacturable. In addition, it is another object of the present invention to make a ferroelectric memory cell which can be integrated with the process to make an embedded product with a controller and an array of ferroelectric memory cells.

### SUMMARY OF THE INVENTION

A ferroelectric memory cell comprises a semiconductor substrate of a first conductivity type having a first region and a second region, spaced apart therefrom. Each of the first and second regions is of a second conductivity type. A channel region is between the first region and the second region. The first region and the second region are aligned in a first direction. A gate dielectric is over at least a portion of the channel region. A gate is over the gate dielectric. The gate extends in a direction transverse to the first direction terminating at a termination point not overlapping with the first region, the second region, or the channel region. A ferroelectric capacitor is at the termination point with the ferroelectric capacitor having a first electrode and a second electrode with the first electrode electrically connected to the gate. The ferroelectric memory cell has three terminals: the first region, the second region, and the second electrode of the ferroelectric capacitor.

The present invention also comprises a nonvolatile integrated memory circuit which has an array of nonvolatile memory cells arranged in a matrix in a plurality of rows and columns in a semiconductor substrate of a first conductivity type. Each of the memory cells is of the type described hereinabove. Cells in the same row have the second regions connected in common and cells in the same column have the second ends connected in common.

Further, in the present invention, a ferroelectric memory cell comprises a semiconductor substrate of a first conductivity type having a first region and a second region spaced apart therefrom. Each of the first region and the second region is of a second conductivity type with a channel region therebetween. A gate dielectric is over at least a portion of the channel region. An insulator is over at least a portion of the first region. A gate has one end over the gate dielectric and extends over the insulator terminating at another end. A ferroelectric capacitor has a first electrode and a second electrode with a first electrode electrically connected to the gate at another end. The ferroelectric memory cell has three terminals: the first region, the second region, and the second electrode.

The present invention is also a nonvolatile integrated memory circuit having an array of nonvolatile memory cells arranged in a matrix in a plurality of rows and columns in a semiconductor substrate of a first conductivity type. Each of the nonvolatile memory cells is of the aforementioned described configuration. Memory cells in the same row have the second regions connected in common and memory cells in the same column have the second ends connected in common.

### BRIEF DESCRIPTION OF THE DRAWINGS

FIG. 1 is a schematic diagram showing a ferroelectric memory cell of the prior art.

FIG. 2 is a schematic diagram of another embodiment of a ferroelectric memory cell of the prior art.

FIG. 3a is a schematic diagram of the improved ferroelectric memory cell of the present invention.

FIG. 3b is a perspective cross-sectional view of the structure of an embodiment of a ferroelectric memory cell of the present invention which is shown schematically in FIG. 3a.

FIG. 4 is a perspective cross-sectional view of the structure of another embodiment of the improved ferroelectric memory cell of the present invention.

FIG. 5 is a perspective cross-sectional view of the structure of yet another embodiment of the ferroelectric memory cell of the present invention.

FIG. 6 is a perspective cross-sectional view of the structure of still another embodiment of the ferroelectric memory cell of the present invention.

FIG. 7 is a schematic diagram of an array of nonvolatile memory cells of the present invention.

FIG. 8 is a perspective cross-sectional view of the structure of still yet another embodiment of the ferroelectric memory cell of the present invention.

FIG. 9 is a block level diagram of an integrated embedded controller containing a microcontroller and an array of ferroelectric nonvolatile memory cells of the present invention.

### DETAILED DESCRIPTION OF THE INVENTION

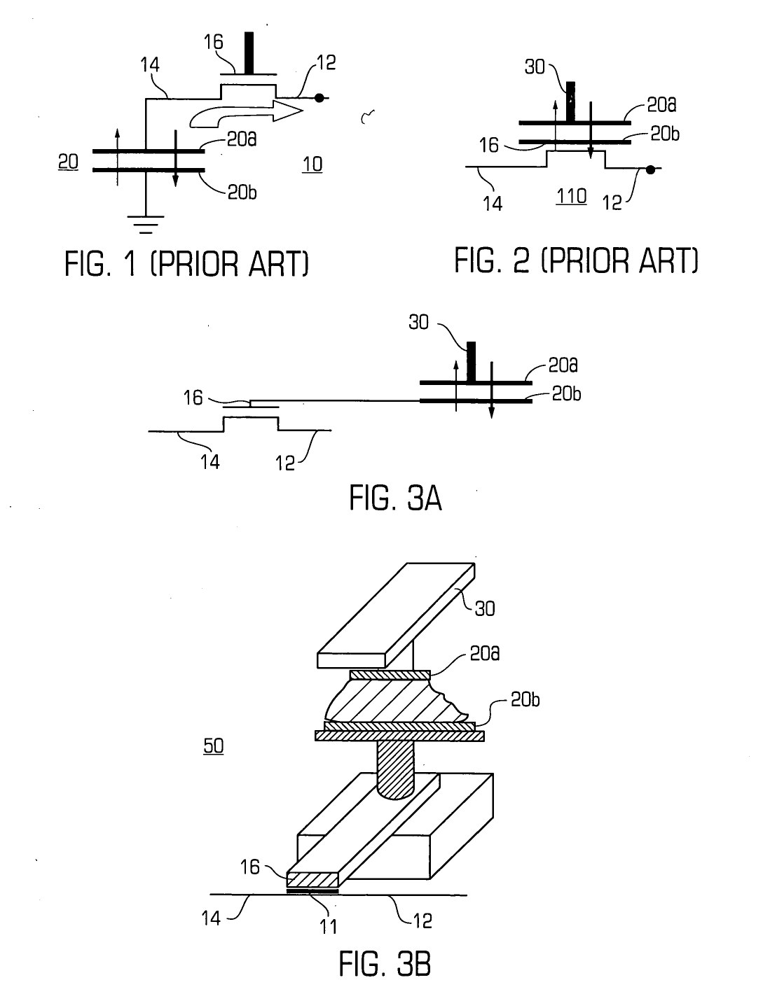

Referring to FIG. 3a, there is shown a schematic diagram of an improved ferroelectric memory cell 50 of the present invention. The ferroelectric memory cell 50, similar to the ferroelectric memory cell 10 and 110 shown in FIGS. 1 and 2 respectively, comprises a conventional MOSFET transistor having a first region 14 and a second region 12, each of which is of a second conductivity type in a semiconductive substrate 8 of a first conductivity type. A channel region is between the first region and the second region 12. A gate dielectric 11 is above the channel region. A gate 16, typically of polysilicon or polycide material or even metal material is on the dielectric 11 and controls the conduction of charges in the channel region. The gate 16 extends in a direction away from the first region 14, the second region 12, and the channel region, and terminates at a termination point which does not overlap with the first region 14, the second region 12 or the channel region. A ferroelectric capacitor 20 having a first electrode 20a and a second electrode 20b is electrically connected to the gate 16 at the termination point. The second electrode 20b is electrically connected to the gate 16. The first electrode 20a is then connected to a control gate 30. Thus, the ferroelectric memory cell 50 of the present invention comprises three terminals: a first region 14, a second region 12, and a control gate 30.

The advantage of the improved ferroelectric memory cell 50 is that the ion milling or etching of the ferroelectric capacitor 20 occurs at a location which is away from the first region 14, second region 12, the channel region or the gate dielectric 11 overlying the channel region. Thus, there would not be any damage to the underlying gate dielectric 11 which is over the channel region, which typically is very thin, on the order of sub 20 Å. The structure upon which the ferroelectric capacitor 20 is formed can be not only the gate material 16 but also an underlying insulator having thousands of angstroms in thickness. Finally, with the improved ferroelectric memory cell 50, it has the advantage of removing concerns associated with “scaling high density” caused by short channel effect. As density increases, and the scale of integration increases, and the channel length is reduced, there is a corresponding reduction in the thickness of the gate oxide over the channel region. Because of this, as scaling increases, a prior art ferroelectric memory cell which is positioned over gate oxide region, will have poor retention time, due to the etching of the ferroelectric capacitor 20 over the gate oxide region. However, with the ferroelectric memory cell 50 of the present invention, because the ferroelectric capacitor 20 is decoupled from the gate oxide 11, the gate 16 and its corresponding gate oxide 11 can be reduced or shrunk without any worry of the affect of etching of the ferroelectric capcitor 20.

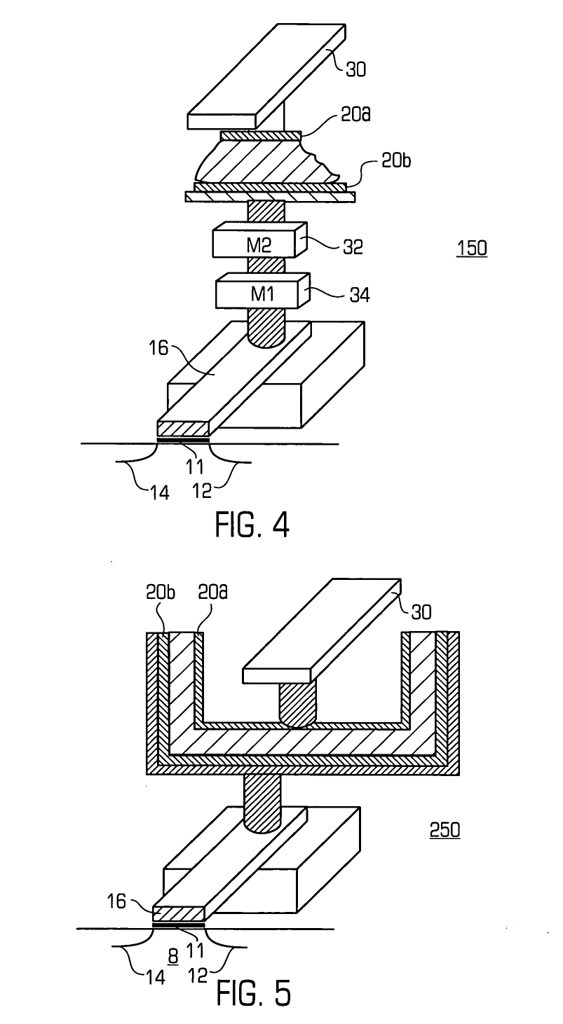

Referring to FIG. 4, there is shown another embodiment of an improved ferroelectric memory cell 150 of the present invention. The improved ferroelectric memory cell 150, similar to the ferroelectric memory cell 50, comprises an MOS transistor having a first region 14, a second region 12, separated by a channel region in a substrate 8. A gate dielectric 11 is on the channel region. A gate 16 is over the gate dielectric 11 and extends in a direction away from the first region 14, the second region 12, and the channel region and ends at a termination point. The terminal point does not overlap with either the first region 14, the second region 12, or the channel region. A plurality of metal layers 34 and 32 are electrically connected to the gate 16. Finally, a ferroelectric capacitor 20 is connected to the plurality of metallization layers 32 and 34, with a second electrode 20b connected to the metal layers 32 and 34. A control gate 30 is electrically connected to the first electrode 20a of the ferroelectric capacitor 20. In this embodiment, since one application of the ferroelectric memory cell 150 is its use in an embedded device, where metal lines are frequently used to increase the speed of operation, the ferroelectric memory cell 150 is “built on” metal lines 32 and 34 which are used in the rest of the embedded device. Typically in an embedded device, the first layer (or the layer for the gate 16) is a polysilicon or silicide layer, and subsequent layers are made of metal; the ferroelectric memory cell 150 is thus built on metal layers 32 and 34 that are “above” the gate 16.

Referring to FIG. 5, there is shown a perspective view of yet another embodiment of a ferroelectric memory cell 250 of the present invention. Similar to the embodiment of the ferroelectric memory cell 150 and 50 shown in FIGS. 4 and 3B, respectively, the ferroelectric memory cell 250 comprises an MOSFET transistor having a first region 14 and a second region 12 of a second conductivity type in a substrate 8 of a first conductivity type. A channel region is between the first region 14 and the second region 12. A gate dielectric 11 is over the channel region. A gate 16 is on the gate dielectric 11. The gate 16 extends in a direction transverse to the direction between the first region 14, the second region 12 and terminates at a point which does not overlap with the first region 14, the second region 12, or the channel region. A ferroelectric capacitor 20 is connected to the gate 16 at that point. A control gate 30 is connected to the ferroelectric capacitor 20. The only difference between the ferroelectric memory cell 250 and the ferroelectric memory cell 50 shown in FIG. 3B is the shape of the ferroelectric capacitor 20. In the embodiment shown in FIG. 5, the ferroelectric capacitor 20 comprises two parallel electrodes 20a and 20b which are not co-planar. In a preferred embodiment, the electrodes 20a and 20b are substantially U-shaped. This U shaped capacitor 20 provides a greater amount of surface area for each of the electrodes 20a and 20B within a volume for the ferroelectric capacitor 20.

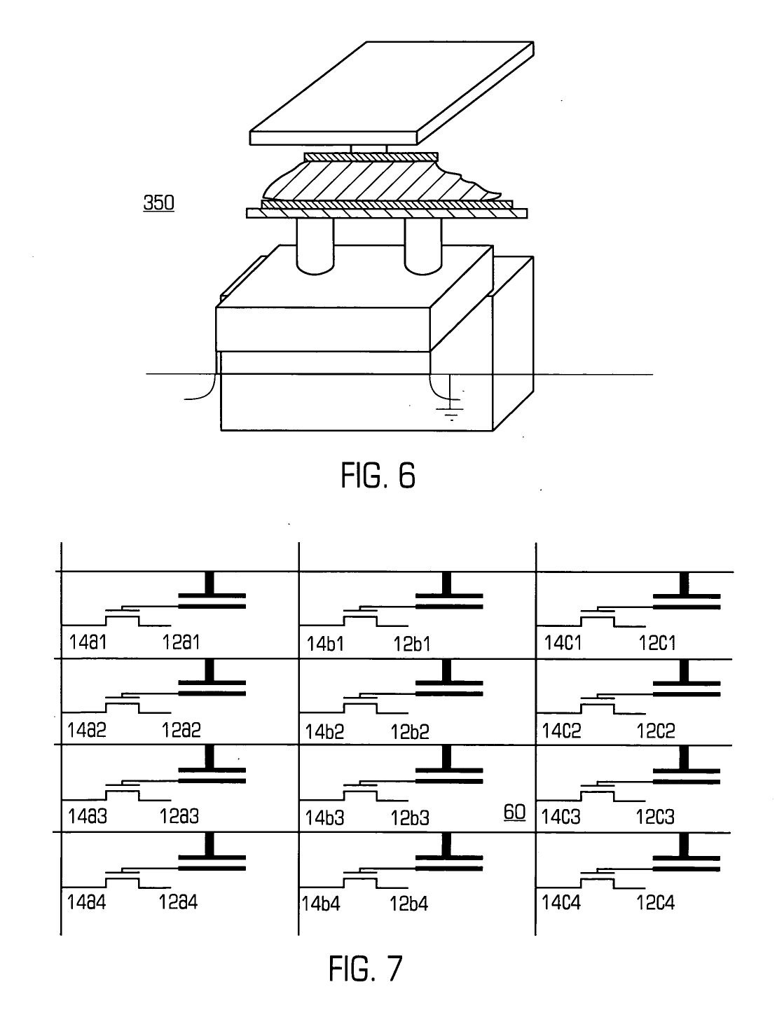

Referring to FIG. 6 there is shown a perspective view of still another embodiment of a ferroelectric memory cell 350 of the present invention. The ferroelectric memory cell 350 is similar to the ferroelectric memory cell 50. As previously discussed, with the embodiment of the ferroelectric memory cell 50, 150, 250 or 350 of the present invention, the “size” of the transistor and in particular the gate 16, and the gate oxide 11, which are determined by the size of the channel region (width and length) can be decoupled from the “size” of the ferroelectric capacitor 20. As a result, where there is a desire to increase the scaling density of the transistor, the ferroelectric capacitor 20 can either be scaled or maintained at the same size. In the embodiment 350 shown in FIG. 6, the opposite can occur. In semiconductor fabs with older fabrication tools where relatively large transistors are made, resulting from a large channel region, the ferroelectric capacitor 20 can be scaled. Thus, in this embodiment the ferroelectric capacitor 20 is made smaller and is scaled while the transistor to which it is connected is not scaled.

Referring to FIG. 7 there is shown a schematic diagram of an array 60 of ferroelectric memory cells 50, 150, 250, or 350 of the present invention. The cells 50, 150, 250 or 350 are arranged in a plurality of rows and columns with cells 50, 150, 250, or 350 lying in the same row having their control gates 30 connected in common. Further, cells 50, 150, 250 and 350 lying in the same column have their first regions 14 connected in common. Selection of a particular cell 50, 150, 250 or 350 within the array 60 is affected by applying appropriate voltages to the selected row line 30 and the selected column line 14, as is well known in the art.

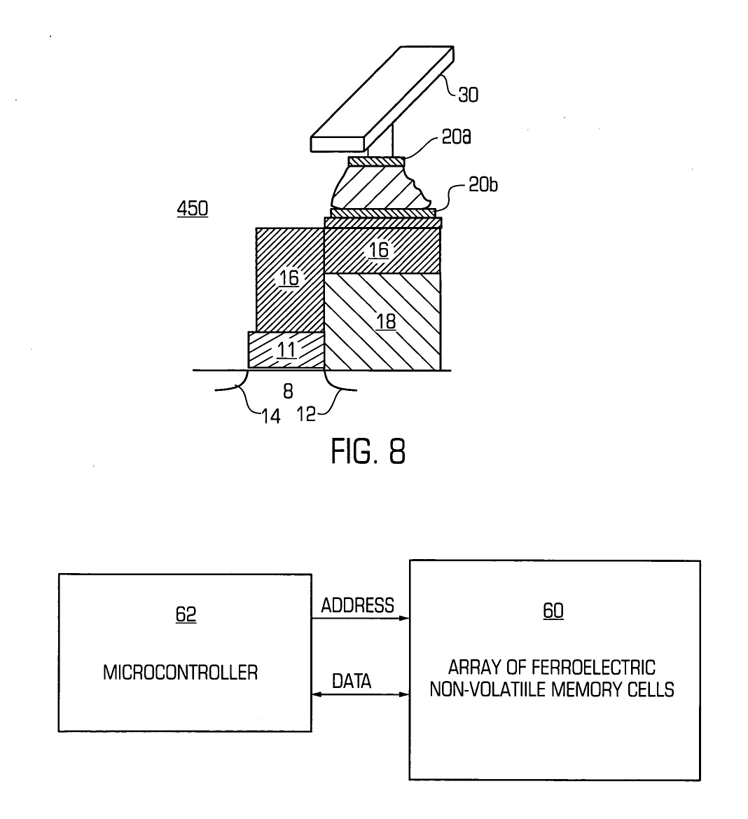

Referring to FIG. 8, there is shown still yet another embodiment of a ferroelectric memory cell 450 of the present invention. Similar to the memory cell 50, 150, 250, and 350, the ferroelectric memory cell 450 comprises an MOSFET transistor having a first region 14, a second region 12, of a second conductivity type in a substrate 8 of a first conductivity type. The first region 14 and the second region 12 are separated by a channel region. A gate dielectric material 11 is over the channel region. An insulating material 18 is over one of the first region 14 or the second region 12. In the drawing shown in FIG. 8, the insulating layer 18 is over the second region 12. A gate 16 is over the gate dielectric 11 and extends to overlie the insulator 18. A ferroelectric capacitor 20 is connected to the gate 16 at the point where the gate 16 overlies the insulator 18. The ferroelectric capacitor 20 has two electrodes: a first electrode 20a and the second electrode 20b with the second electrode 20b connected to the gate 16. A control gate 30 is connected to the first electrode 20a.

The insulator 18 is relatively thick, such as 2000 Å-6000 Å and is much thicker than the gate dielectric 11. Further, connection to the second region 12 can be made by either a buried contact, or by a contact adjacent to the insulator 18. The advantage of the embodiment of the ferroelectric memory cell 450 shown in FIG. 8 is that it is more compact than the ferroelectric memory cell 50, 150, 250 or 350. However, it does require at least one extra masking step to form the structure. Because the ferroelectric capacitor 20 is constructed “on top” of the gate 16 which is on a relatively thick insulator 18, the problems of the ion milling of the ferroelectric capacitor 20 being unable to stop on a thin gate dielectric can be avoided. Further, any potential damage of the thin gate oxide 11 is also avoided.

The ferroelectric memory cell 450 shown in FIG. 8 can also be made into an array 60 connected in the manner shown in FIG. 7.

Although each of the embodiments 50, 150, 250, 350 and 450 of the ferroelectric memory cell can be used in an array 60, it is preferred that only the memory cell 450 shown in FIG. 8 be used in an integrated circuit memory device. This is because the memory cell 450 of the embodiment shown in FIG. 8 is the most compact of all the designs. However, as previously stated, each of the ferroelectric memory cells 50, 150, 250 and 350 may also be used in an array to form an integrated circuit memory device.

The embodiments of the memory cell 50, 150, 250 and 350 are best used in an array 60 as an integrated embedded controller device, whose schematic diagram is shown in FIG. 9. As an integrated embedded controller device, the device has a microcontroller or controller 62 connected to an array of ferroelectric nonvolatile memory cells 60. Because the microcontroller 62 has logic components thereto, such as an ALU, comparator, etc., and has metallization layers that increase the performance of the processing of the microcontroller 62, the process of making the memory cell 50, 150, 250 or 350 used in the array 60 is more compatible with the process to make the microcontroller 62. Thus, in an integrated embedded controller device wherein a microcontroller and an array of nonvolatile memory cells are integrated together, the embodiment 50, 150, 250 or 350 of the memory cell is preferred.

It should be noted that as used herein and in the claims the term “substrate” includes “well”. Further, the substrate can be of any type of conductivity, such P or N. Finally, the term “semiconductor” includes single material crystalline, or recrystallized or epitaxially grown single material crystalline or compound material crystalline.

1. A ferroelectric memory cell comprising:
a semiconductor substrate of a first conductivity type having a first region and a second region each of a second conductivity type, with a channel region therebetween; said first region and second region aligned in a first direction;
a gate dielectric over at least a portion of said channel region;
a gate over said gate dielectric, said gate extending in a direction transverse to said first direction termination at a point not overlapping said first region, said second region and said channel region; and
a ferroelectric capacitor at said point, said ferroelectric capacitor having a first end and a second end, said first end connected to said gate;
wherein said ferroelectric memory cell having three terminals: said first region, said second region, and said second end.

2. A ferroelectric memory cell comprising:
a semiconductor substrate of a first conductivity type having a first region and a second region each of a second conductivity type, with a channel region therebetween;
a gate dielectric over at least a portion of said channel region;
an insulator over at least a portion of said first region;
a gate having one end over said gate dielectric and extending over said insulator terminating at another end; and
a ferroelectric capacitor having a first end and a second end with said first end electrically connected to said gate at said another end;
wherein said ferroelectric memory cell having three terminals: said first region, said second region and said second end.

3. The ferroelectric memory cell of claims 1 and 2 wherein said gate is polysilicon.

4. The ferroelectric memory cell of claims 1 and 2 wherein said gate is a floating gate, and further comprising:
a second gate between said floating and said gate dielectric and insulated from said floating gate.

5. The ferroelectric memory cell of claims 1 and 2 wherein said ferroelectric cell comprises a first non-planar electrode and a second non-planar electrode separated from said first electrode.

6. The ferroelectric memory cell of claims 1 and 2 wherein said ferroelectric cell is substantially U-shaped.

7. A non-volatile integrated memory circuit comprising:
an array of non-volatile memory cells arranged in a matrix in a plurality of rows and columns, in a semiconductor substrate of a first conductivity type;
each memory cell comprising:
a first region and a second region each of a second conductivity type in said substrate, with a channel therebetween;
a gate dielectric over at least a portion of said channel region;
an insulator over at least a portion of said first region;
a gate having one end over said gate dielectric and extending over said insulator terminating at another end;
a ferroelectric capacitor having a first end and a second end with said first end electrically connected to said gate at said another end;
wherein said ferroelectric memory cell having three terminals: said first region, said second region and said second end;
wherein said cells in the same row have said second regions connected in common, and
wherein said cells in the same column have said second end connected in common.

8. An integrated embedded circuit comprising:
an array of non-volatile memory cells arranged in a matrix in a plurality of rows and columns, in a semiconductor substrate of a first conductivity type;
each memory cell comprising:
a first region and a second region each of a second conductivity type in said substrate, with a channel therebetween; said first region and second region aligned in a first direction;
a gate dielectric over at least a portion of said channel region;
a gate over said gate dielectric, said gate extending in a direction transverse to said first direction terminating at a point not overlapping with said first region, said second region and said channel region; and
a ferroelectric capacitor at said point, said ferroelectric capacitor having a first end and a second end, said first end connected to said gate;
wherein said ferroelectric memory cell having three terminals: said first region, said second region, and said second end;
wherein said cells in the same row have said second regions connected in common;
wherein said cells in the same column have said second end connected in common; and
a controller integrated with said array for storing programs in said array executable by said controller.

9. A non-volatile integrated memory circuit comprising:
an array of non-volatile memory cells arranged in a matrix in a plurality of rows and columns, in a semiconductor substrate of a first conductivity type;
each memory cell comprising:
a first region and a second region each of a second conductivity type in said substrate, with a channel therebetween; said first region and second region aligned in a first direction;
a gate dielectric over at least a portion of said channel region;
a gate over said gate dielectric, said gate extending in a direction transverse to said first direction terminating at a point not overlapping with said first region, said second region and said channel region; and
a ferroelectric capacitor at said point, said ferroelectric capacitor having a first end and a second end, said first end connected to said gate;
wherein said ferroelectric memory cell having three terminals: said first region, said second region, and said second end;
wherein said cells in the same row have said second regions connected in common; and
wherein said cells in the same column have said second end connected in common.

10. The ferroelectric memory cell of claims 7, 8 and 9 wherein said gate is polysilicon.

11. The ferroelectric memory cell of claims 7, 8, and 9 wherein said gate is a floating gate, and fiber comprising:
a second gate between said floating and said gate dielectric and insulated from said floating gate.

12. The ferroelectric memory cell of claims 7, 8, and 9 wherein said ferroelectric cell comprises a first non-planar electrode and a second non-planar electrode separated from said first electrode.

13. The ferroelectric memory cell of claims 7, 8, and 9 wherein said ferroelectric cell is substantially U-shaped.
